(19) United States
(12) Patent Application Publication
(10) Pub. No.: US 2008/0102609 A1
(43) Pub. Date: May 1, 2008

(54) Method for producing a wired circuit board

(75) Inventors: Jun Ishii, Osaka (JP); Yasunari Ooyabu, Osaka (JP); Hiroyuki Kurai, Osaka (JP)

Correspondence Address: AKERMAN SENTERFITT, 801 PENNSYLVANIA AVENUE N.W., SUITE 600, WASHINGTON, DC, 20004, US

(73) Assignee: Nitto Denko Corporation, Osaka (JP)

(21) Appl. No.: 11/976,235

(22) Filed: Oct. 23, 2007

Related U.S. Application Data
(60) Provisional application No. 60/907,022, filed on Mar. 16, 2007.

(30) Foreign Application Priority Data
Oct. 30, 2006 (JP) 2006-294621

(51) Int. Cl. H01L 21/20

(52) U.S. Cl. 438/479; 257/E21.09

(57) ABSTRACT

A method for producing a wired circuit board includes the steps of preparing a wired circuit board including an insulating layer and a conductive pattern having a wire covered with the insulating layer and a terminal portion exposed from the insulating layer, and forming a semiconductive layer on a surface of the insulating layer by dipping the wired circuit board in a polymeric liquid of a conductive polymer. An oxidation-reduction potential of the polymeric liquid of the conductive polymer is lower than a standard electrode potential of a conductive material forming the conductive pattern.

### CROSS-REFERENCE TO RELATED APPLICATION

This patent application claims the benefit of U.S. Provisional Application No. 60/907,022, filed on Mar. 16, 2007, and claims priority from Japanese Patent Application No. 2006-294621, filed on Oct. 30, 2006, the contents of which are herein incorporated by reference in their entirety.

### BACKGROUND OF THE INVENTION

1. Field of the Invention

The present invention relates to a method for producing a wired circuit board. More particularly, the present invention relates to a method for producing a wired circuit board such as a suspension board with circuit.

2. Description of Related Art

There has been conventionally known a wired circuit board on which an insulating base layer, a conductive pattern having a wire and a terminal portion, and an insulating cover layer are sequentially laminated. The wired circuit boards of this type are widely used in a variety of fields of electric and electronic equipment.

As a method for producing such wired circuit board, in order to prevent electrostatic breakdown of electronic components to be mounted thereon, for example, there has been proposed a method for producing a flexible printed circuit board obtained by producing a laminated body (board body) made of a base layer, a conductor circuit, and a cover layer, and then forming a conductive polymer layer around the laminated body (cf., Japanese Unexamined Patent Publication No. 2004-158480).

### SUMMARY OF THE INVENTION

In the method for producing a flexible printed circuit board described in Japanese Unexamined Patent Publication No. 2004-158480, a laminated body is dipped in an oxidizing treatment liquid containing pyrrole as a monomer and potassium peroxodisulfate as an oxidizing-polymerizing agent to form a conductive polymer layer. Therefore, such treatment liquid may dissolve a conductive material which forms a conductive circuit at a terminal portion exposed from a cover layer in the conductive circuit. This may corrode the terminal portion to cause discoloration therein.

It is an object of the present invention to provide a method for producing a wired circuit board capable of preventing discoloration of a terminal portion and also efficiently removing static electricity charged on the resulting wired circuit board.

The method for producing a wired circuit board according to the present invention includes the steps of preparing a wired circuit board including an insulating layer and a conductive pattern having a wire covered with the insulating layer and a terminal portion exposed from the insulating layer, and forming a semiconductive layer on a surface of the insulating layer by dipping the wired circuit board in a polymeric liquid of a conductive polymer, wherein an oxidation-reduction potential of the polymeric liquid of the conductive polymer is lower than a standard electrode potential of a conductive material forming the conductive pattern.

According to the method for producing a wired circuit board, the oxidation power of the polymeric liquid of the conductive polymer becomes lower than that of the conductive material forming the conductive pattern. Therefore, when the wired circuit board is dipped in the polymeric liquid of the conductive polymer, the conductive material forming the conductive pattern is less likely to be dissolved in the polymeric liquid, even if it is exposed in the terminal portion.

Accordingly, a semiconductive layer can be formed on a surface of an insulating layer while corrosion in the terminal portion can be prevented.

As a result, static electricity charged on the resulting wired circuit board can be efficiently removed while discoloration in the terminal portion can be prevented.

In the method for producing a wired circuit board according to the present invention, it is preferable that in the step of preparing the wired circuit board, a plating layer is formed on a surface of the terminal portion.

In general, in producing methods of a wired circuit board, in order to protect a terminal portion, a plating layer may be formed on a surface thereof. However, when the wired circuit board is dipped in a polymeric liquid of a conductive polymer, the polymeric liquid permeates the interface between a peripheral end portion of the plating layer and an insulating layer. This may dissolve a conductive material in the terminal portion to cause corrosion in the terminal portion.

However, in this method for producing a wired circuit board, since the oxidation power of the polymeric liquid of the conductive polymer becomes lower than that of the conductive material that forms the conductive pattern, the conductive material in the terminal portion is less likely to be dissolved. Therefore, even if a plating layer is formed on a surface of the terminal portion, and the polymeric liquid of the conductive polymer permeates the interface between the peripheral end portion of the plating layer and the insulating layer, such corrosion is less likely to occur, whereby discoloration in the terminal portion can be effectively prevented.

In the method for producing a wired circuit board according to the present invention, it is preferable that the conductive material of the conductive pattern is copper, and the polymeric liquid contains sulfonic acid.

In this method, since the conductive material of the conductive pattern is copper, when the polymeric liquid contains sulfonic acid, the oxidation power of the polymeric liquid can be reliably adjusted lower than that of the conductive pattern. Therefore, in the terminal portion, dissolution of the copper in the polymeric liquid is reliably suppressed.

Accordingly, corrosion in the terminal portion can be reliably prevented. As a result, discoloration in the terminal portion can be reliably prevented.

In the method for producing a wired circuit board according to the present invention, it is preferable that the conductive polymer is polyaniline.

In this method for producing a wired circuit board, since the conductive polymer is polyaniline, the resulting wired circuit board can more efficiently remove static electricity charged thereon.

### BRIEF DESCRIPTION OF THE DRAWINGS

FIG. 1 is a plan view illustrating a suspension board with circuit as an embodiment of a wired circuit board produced by a method for producing a wired circuit board according to the present invention;

FIG. 2 is a sectional view of the suspension board with circuit taken along the line A-A shown in FIG. 1;

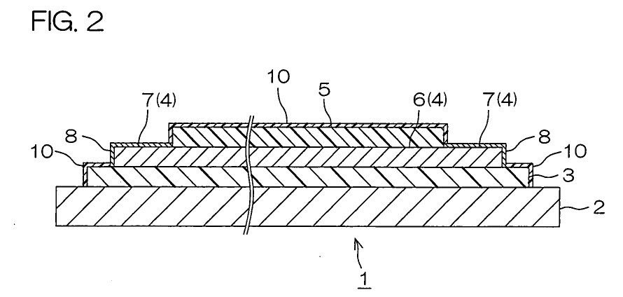

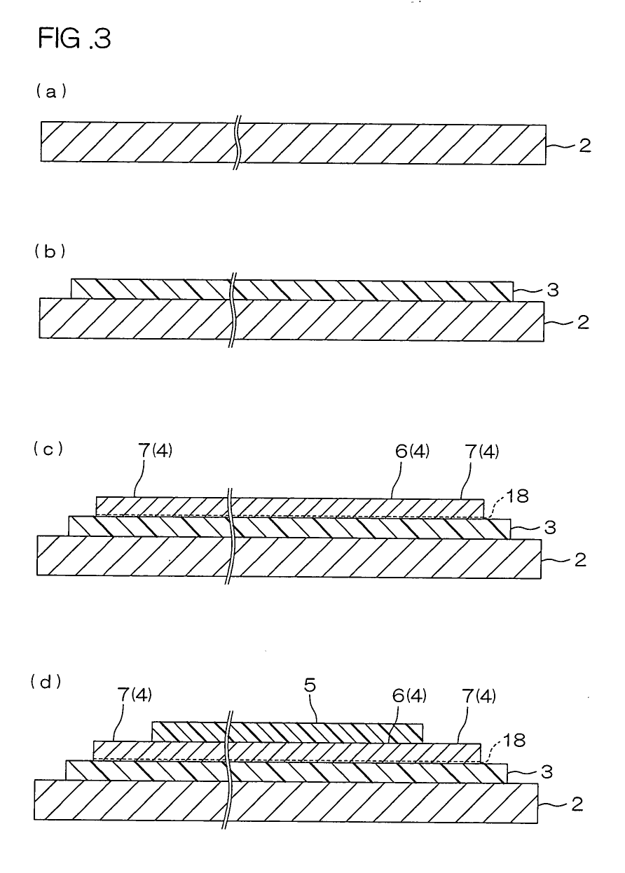

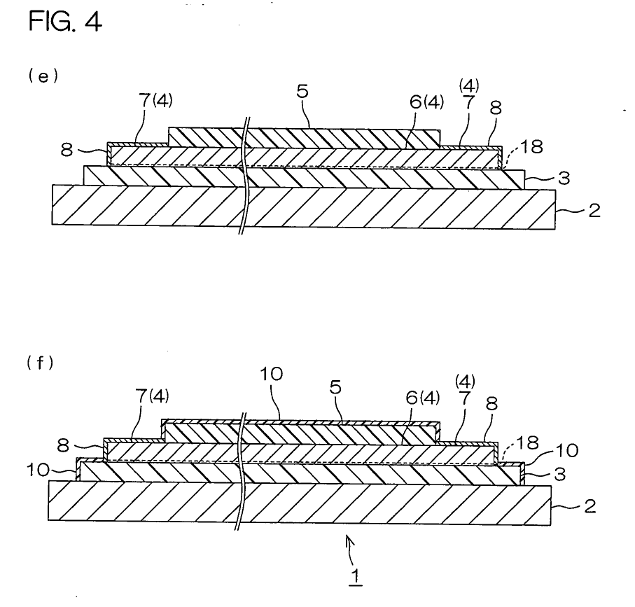

FIG. 3 is a sectional view illustrating the steps of producing a suspension board with circuit shown in FIG. 2,
(a) showing the step of preparing a metal supporting board,
(b) showing the step of forming an insulating base layer on the metal supporting board,
(c) showing the step of forming a conductive pattern on the insulating base layer, and
(d) showing the step of forming an insulating cover layer on the insulating base layer; and

FIG. 4 is a sectional view illustrating the steps of producing the suspension board with circuit shown in FIG. 2, subsequent to FIG. 3,
(e) showing the step of forming a plating layer on a surface of a terminal portion, and
(f) showing the step of forming a semiconductive layer on the surface of the insulating cover layer and the surface of the insulating base layer.

### DETAILED DESCRIPTION OF THE INVENTION

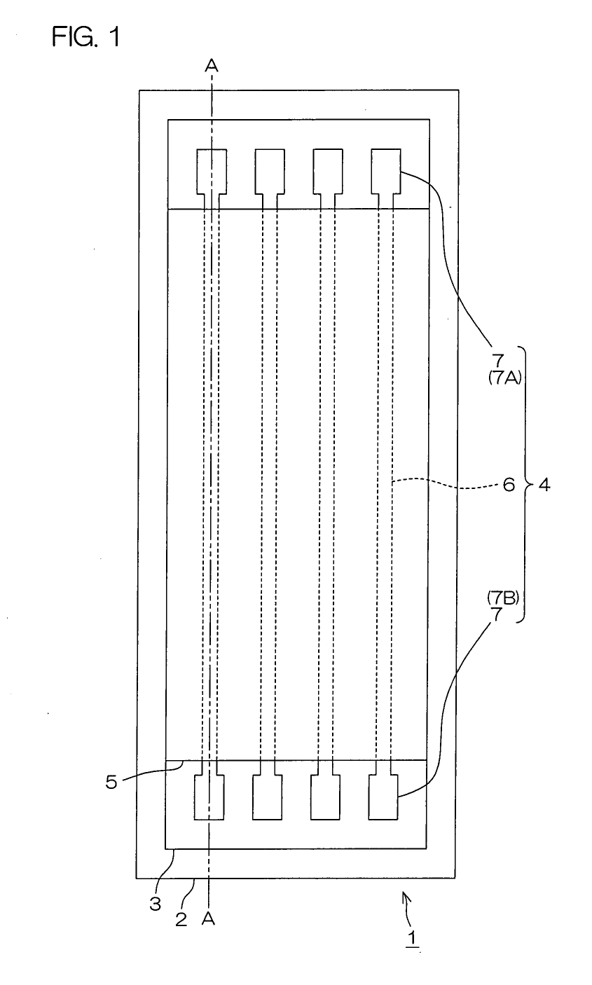

FIG. 1 is a plan view illustrating a suspension board with circuit as an embodiment of a wired circuit board produced by a method for producing a wired circuit board according to the present invention, and FIG. 2 is a sectional view of the suspension board with circuit taken along the line A-A shown in FIG. 1.

In FIG. 1, the suspension board with circuit 1 includes a metal supporting board 2 mounted on a hard disk drive. A conductive pattern 4 for connecting a magnetic head (not shown) and a read/write board (not shown) is formed on the metal supporting board 2. The metal supporting board 2 supports the magnetic head mounted thereon, while holding a minute gap between the magnetic head and a magnetic disk against an airflow caused when the magnetic head and the magnetic disk travel relatively to each other.

To clarify the arrangement of the conductive pattern 4, a plating layer 8 and a semiconductive layer 10, both mentioned later, are omitted in FIG. 1.

The conductive pattern 4 includes magnetic-head-side connecting terminal portions 7A, external connecting terminal portions 7B, and wires 6 for connecting therebetween, which are formed integrally and continuously.

The wires 6 are provided along a longitudinal direction (hereinafter simply referred to as “lengthwise direction”) of the suspension board with circuit 1, and a plurality (four pieces) of the wires 6 are arranged in parallel at spaced intervals to each other in the widthwise direction (the direction orthogonal to the lengthwise direction; the same applies hereinafter).

The magnetic-head-side connecting terminal portions 7A are arranged at a front end portion of the metal supporting board 2 in parallel at spaced intervals to each other along the widthwise direction, and each formed as an angled land having a generally rectangular shape in plane view extending in the lengthwise direction. The plurality (four pieces) of the magnetic-head-side connecting terminal portions 7A are provided so that the front end portions of the respective wires 6 are connected thereto. Terminal portions (not shown) of the magnetic head are to be connected to the magnetic-head-side connecting terminal portions 7A.

The external connecting terminal portions 7B are arranged at a rear end portion of the metal supporting board 2 in parallel at spaced intervals to each other along the widthwise direction, and each formed as an angled land having a generally rectangular shape in plane view extending in the lengthwise direction. The plurality (four pieces) of the external connecting terminal portions 7B are provided so that the rear end portions of the respective wires 6 are connected thereto. Terminal portions (not shown) of the read/write board are to be connected to the external connecting terminal portions 7B.

The magnetic-head-side connecting terminal portions 7A and the external connecting terminal portions 7B are hereinafter simply described as “the terminal portion 7”, when no particular distinction is required.

As shown in FIG. 2, the suspension board with circuit 1 includes a metal supporting board 2, an insulating base layer 3 formed on the metal supporting board 2, a conductive pattern 4 formed on the insulating base layer 3, and an insulating cover layer 5 formed on the insulating base layer 3 so as to cover the conductive pattern 4. The suspension board with circuit 1 also includes a plating layer 8 formed on a surface of the terminal portion 7 of the conductive pattern 4, and a semiconductive layer 10 formed on the surface of the insulating cover layer 5 and the surface of the insulating base layer 3.

The metal supporting board 2 is formed in a generally rectangular sheet shape in plane view extending along the lengthwise direction as shown in FIG. 1. The metal supporting board 2 is formed of a metal material, such as stainless steel, 42-alloy, aluminum, copper-beryllium, or phosphor bronze. The metal supporting board 2 has a thickness in the range of, for example, 15 to 30 μm, or preferably 20 to 25 μm.

The insulating base layer 3 is formed on the metal supporting board 2 so as to have a generally rectangular sheet shape in plane view slightly shorter in the lengthwise direction and the widthwise direction than the metal supporting board 2, as shown in FIGS. 1 and 2. The insulating base layer 3 is formed of an insulating material such as synthetic resin, including polyimide resin, polyamide imide resin, acrylic resin, polyether nitrile resin, polyether sulfone resin, polyethylene terephthalate resin, polyethylene naphthalate resin, polyvinyl chloride resin, or the like. The insulating base layer 3 is preferably formed of polyimide resin. The insulating base layer 3 has a thickness in the range of, for example, 1 to 35 μm, or preferably 8 to 15 μm. The length (length in lengthwise direction; the same applies hereinafter) and width (length in widthwise direction; the same applies hereinafter) of the insulating base layer 3 are appropriately set corresponding to the metal supporting board 2.

The conductive pattern 4 is formed on the insulating base layer 3 in a wired circuit pattern which is integrally formed of the wire 6 and the terminal portions 7 connected to the wire 6.

The wire 6 is formed so as to be covered with the insulating cover layer 5.

The terminal portion 7 is formed in both lengthwise end portions of the insulating base layer 3 so as to be exposed from both end portions of the insulating cover layer 5.

The conductive pattern 4 is formed of a conductive material having a standard electrode potential (25° C.) in the range of, for example, 0.1 to 2.0 V, or preferably 0.1 to 0.5 V More specifically, the conductive pattern 4 is formed of a conductive material such as copper (standard electrode potential (25° C.): 0.337 V), gold (standard electrode potential (25° C.): 1.50 V), or alloys thereof. The conductive pattern 4 is preferably formed of copper.

The conductive pattern 4 has a thickness in the range of, for example, 3 to 50 μm, or preferably 5 to 20 μm. Each of the wires 6 has a width in the range of, for example, 10 to 200 μm, or preferably 20 to 100 μm, and a spacing between each of the wires 6 is in the range of, for example, 10 to 1000 μm, or preferably 20 to 100 μm. Each of the terminal portions 7 has a length in the range of, for example, 50 to 2000 μm, or preferably 100 to 1000 μm, and has a width in the range of, for example, 50 2000 μm, or preferably 100 to 1000 μm.

The insulating cover layer 5 is formed in a generally rectangular sheet shape in plane view extending along the lengthwise direction. More specifically, in the widthwise direction, the insulating cover layer 5 is arranged so that both widthwise end edges thereof are in the same position as both widthwise end edges of the insulating base layer 3 in plane view. Further, in the lengthwise direction, the insulating cover layer 5 is arranged so that both lengthwise end edges thereof are slightly shorter than both lengthwise end edges of the insulating base layer 3. Accordingly, the insulating cover layer 5 covers the wire 6 of the conductive pattern 4, and exposes the terminal portions 7 of the conductive pattern 4. The insulating cover layer 5 is formed of the same insulating material as of the above-mentioned insulating base layer 3.

The insulating cover layer 5 has a thickness in the range of, for example, 1 to 40 μm, or preferably, 1 to 7 μm. The length of the insulating cover layer 5 is appropriately set depending on the size of the insulating base layer 3 and the terminal portion 7.

The plating layer 8 is formed on the upper surface, both lengthwise side surfaces, and both widthwise side surfaces (not shown in FIG. 2) of the terminal portion 7. A metal material such as gold is used as a material of the plating layer 8, for example. The plating layer 8 has a thickness in the range of, for example, 0.2 to 3 μm, or preferably 0.5 to 2 μm.

The semiconductive layer 10 is formed on the upper surface, both lengthwise side surfaces, and both widthwise side surfaces (not shown in FIG. 2) of the insulating cover layer 5, and on the upper surface, both lengthwise side surfaces, and both widthwise side surfaces (not shown in FIG. 2) of the insulating base layer 3 exposed from the insulating cover layer 5 and the conductive pattern 4.

The semiconductive layer 10 is formed of a conductive polymer by dipping in a polymeric liquid of a conductive polymer described later.

The conductive polymer includes, for example, polyaniline, polypyrrole, and polythiophene, or a derivative thereof. The conductive polymer is preferably polyaniline. These conductive polymers can be used alone or in combination of two or more kinds.

The semiconductive layer 10 has a thickness in the range of, for example, 0.01 to 0.1 μm, or preferably 0.02 to 0.05 μm.

Next, a method for producing the suspension board with circuit 1 is described with reference to FIGS. 3 and 4.

In this method, a metal supporting board 2 is first prepared, as shown in FIG. 3(a).

Then, in this method, an insulating base layer 3 is formed on the metal supporting board 2 in the above-mentioned pattern, as shown in FIG. 3(b).

To form the insulating base layer 3 in the above-mentioned pattern, for example, a varnish of the photosensitive, insulating material described above is coated over the upper surface of the metal supporting board 2 and then dried. Thereafter, the coated varnish is exposed to light via a photomask, and then developed to be cured as required.

Subsequently, in this method, as shown in FIG. 3 (c), a conductive pattern 4 is formed on the insulating base layer 3 in the above-mentioned wired circuit pattern.

The conductive pattern 4 is formed by a known patterning method, such as an additive method or a subtractive method. The conductive pattern 4 is formed preferably by the additive method.

In the additive method, a metal thin film 18 shown in phantom line is first formed on the upper surface, both lengthwise side surfaces, and both widthwise side surfaces of the insulating base layer 3, and on the upper surface of the metal supporting board 2 exposed from the insulating base layer 3. The metal thin film 18 is formed by laminating a thin chromium film and a thin copper film by sputtering, or preferably chromium sputtering and copper sputtering.

Then, after a plating resist, which is not shown, is formed in a pattern reverse to the above-mentioned pattern on the upper surface of the metal thin film 18, the conductive pattern 4 is formed on the upper surface of the metal thin film 18 exposed from the plating resist in the above-mentioned pattern by electrolytic plating. Thereafter, the plating resist and the metal thin film 18 on which the plating resist is laminated are removed.

Thus, the conductive pattern 4 can be formed on the insulating base layer 3 in the above-mentioned wired circuit pattern.

Then, in this method, as shown in FIG. 3 (d), the insulating cover layer 5 is formed on the insulating base layer 3 in a pattern which covers the wire 6 of the conductive pattern 4 and exposes the terminal portion 7 of the conductive pattern 4.

To form the insulating cover layer 5 in the above-mentioned pattern, for example, a varnish of the photosensitive, insulating material described above is coated over the upper surface of the metal supporting board 2 including the conductive pattern 4 and the insulating base layer 3 and then dried. Thereafter, the coated varnish is exposed to light via a photomask, and then developed to be cured as required.

Subsequently, in this method, as shown in FIG. 4 (e), a plating layer 8 is formed on the surface of the terminal portion 7.

To form the plating layer 8, for example, a plating resist, which is not shown, is formed so as to cover the metal supporting board 2, and thereafter, for example, the surface of the terminal portion 7 exposed from the plating resist thus formed is subjected to electrolytic plating or electroless plating, or preferably electrolytic gold plating or electroless gold plating. Thereafter, the plating resist is removed.

Thus, a suspension board with circuit 1 in a production process (suspension board with circuit 1 before the semiconductive layer 10 is formed), including the insulating base layer 3 and the insulating cover layer 5, and the conductive pattern 4, is prepared.

In the suspension board with circuit 1 in a production process, the conductive pattern 4 integrally includes the wire 6 covered with the insulating cover layer 5, and the terminal portion 7 exposed from the insulating cover layer 5 and having the plating layer 8 formed on the surface thereof.

Subsequently, in this method, as shown in FIG. 4 (f), the semiconductive layer 10 is formed on the surface of the insulating cover layer 5 and the surface of the insulating base layer 3.

To form the semiconductive layer 10, first, the suspension board with circuit 1 in a production process shown in FIG. 4 (e) is dipped in a polymeric liquid of a conductive polymer, and a polymerization initiator is also mixed with the polymeric liquid.

The polymeric liquid of the conductive polymer is prepared so as to have a lower oxidation-reduction potential than the standard electrode potential of the conductive material that forms the conductive pattern 4. Such polymeric liquid of the conductive polymer contains, for example, a monomer and a solvent for polymerizing the conductive polymer, and is prepared by mixing them.

The monomer that may be used includes, for example, aniline, pyrrole, and thiophene, or preferably aniline is used. These monomers can be used alone or in combination of two or more kinds.

The solvent that may be used includes, for example, water, and an acidic aqueous solution, or preferably the acidic aqueous solution is used.

An organic acid such as sulfonic acid is used as an acid component which forms the acidic aqueous solution, for example.

The sulfonic acid that may be used includes, for example, methanesulfonic acid, 1,5-naphthalenedisulfonic acid, p-toluenesulfonic acid, polystyrenesulfonic acid, polyvinylsulfonic acid, and sulfosuccinic acid, or preferably methanesulfonic acid is used.

The polymerization initiator that may be used includes, for example, an azo initiator such as 2,2′-azobisisobutyronitrile, 2,2′-azobis(2-methylpropione amidine) disulfate, or 2,2′-azobis(2-methylpropione amidine) dihydrochloride; a persulfate initiator such as potassium persulfate (potassium peroxodisulfate) or ammonium persulfate (ammonium peroxodisulfate); an iodate initiator such as sodium iodate or potassium iodate; a peroxide initiator such as benzoyl peroxide, t-butyl hydroperoxide, or hydrogen peroxide; a substituted ethane initiator such as phenyl substituted ethane; a carbonyl initiator such as an aromatic carbonyl compound; and a redox initiator such as a combination of a persulfate and sodium hydrogensulfite or a combination of a peroxide and sodium ascorbate. The persulfate initiator is preferably used. These polymerization initiators can be used alone or in combination of two or more kinds.

To mix a polymerization initiator with the polymeric liquid, a polymerization initiator solution obtained by dissolving a polymerization initiator in a solvent is prepared as required, and the polymerization initiator solution thus obtained can also be mixed. As the solvent used for preparation of the polymerization initiator solution, the same solvent as that used for preparation of the polymeric liquid is used.

When the polymerization initiator (or polymerization initiator solution) is mixed with the polymeric liquid of the conductive polymer, the polymeric liquid is prepared so as to have an oxidation-reduction potential (25° C.) in the range of, for example, 0.03 to 0.5 V lower than the standard electrode potential (25° C.) of the conductive material that forms the conductive pattern 4, or preferably 0.2 to 0.5 V lower. More specifically, when the polymerization initiator (or polymerization initiator solution) is mixed with the polymeric liquid of the conductive polymer, the polymeric liquid is prepared so as to have an oxidation-reduction potential (25° C.) in the range of, for example, 0 to 0.3 V, or preferably 0 to 0.2 V.

The oxidation-reduction potential (25° C.) of such polymerization liquid of the conductive polymer can be measured with a potentiostat.

In order to adjust the oxidation-reduction potential (25° C.) of the above-mentioned polymeric liquid of the conductive polymer lower than the standard electrode potential (25° C.) of the conductive material that forms the conductive pattern 4, the concentration of monomers in the polymeric liquid of the conductive polymer is in the range of, for example, 0.005 to 0.5 mol/L, or preferably 0.01 to 0.1 mol/L. In a case where the solvent is an acidic aqueous solution, the concentration of acidic components is in the range of, for example, 0.004 to 0.2 mol/L, or preferably 0.01 to 0.1 mol/L. Further, when the polymerization initiator (or polymerization initiator solution) is mixed with the polymeric liquid, the concentration of the polymerization initiator in the polymeric liquid is in the range of, for example, 0.002 to 0.2 mol/L, or preferably 0.005 to 0.1 mol/L.

Then, the above-mentioned suspension board with circuit 1 is dipped in the polymeric liquid of the conductive polymer and mixed with the polymerization initiator. Thereafter, the suspension board with circuit 1 is kept dipped for 5 to 180 minutes, or preferably for 10 to 100 minutes.

In the above-mentioned dipping, the dipping temperature of the polymeric liquid of the conductive polymer is set in the range of, for example, 1 to 40° C., or preferably 5 to 25° C.

Accordingly, the semiconductive layer 10 made of the conductive polymer is formed by polymerization so as to be deposited on a surface of an insulating layer, that is, the surface of the insulating cover layer 5 and the surface of the insulating base layer 3.

Thereafter, the suspension board with circuit 1 in a production process having the semiconductive layer 10 thus formed is washed with water.

Subsequently, in this method, the conductive polymer of the semiconductive layer 10 is doped as required.

To dope the conductive polymer of the semiconductive layer 10, the suspension board with circuit 1 having the above-mentioned semiconductive layer 10 thus formed is dipped in a solution in which a doping agent is dissolved (the solution of the doping agent).

The doping agent imparts conductivity to the conductive polymer, and the doping agent that may be used includes, for example, p-toluenesulfonic acid, dodecylbenzenesulfonic acid, alkylnaphthalenesulfonic acid, polystyrenesulfonic acid, p-toluenesulfonic acid novolac resin, p-phenolsulfonic acid novolac resin, and β-naphthalenesulfonic acid-formalin condensate. These doping agents can be used alone or in combination of two or more kinds.

For example, water or methanol is used as a solvent for dissolving the doping agent.

In preparation of a doping agent solution, the solvent is mixed so that the concentration of the doping agent is in the range of, for example, 5 to 100% by weight, or preferably 10 to 50% by weight.

The dipping time of the suspension board with circuit 1 formed with the semiconductive layer 10, in the doping agent solution is set in the range of, for example, 30 seconds to 30 minutes, or preferably 1 to 10 minutes.

The dipping (doping) temperature of the doping agent solution is set in the range of, for example, 10 to 70° C., or preferably 20 to 60° C.

The doping of the above-mentioned semiconductive layer 10 with the conductive polymer imparts conductivity to the conductive polymer.

The surface resistance value of the semiconductive layer 10 doped with the conductive polymer is in the range of, for example, 1×10⁵ to 1×10¹²Ω/□, or preferably 1×10⁶ to 1×10¹¹Ω/□. The surface resistance value of the semiconductive layer 10 can be measured, for example, using Hiresta IP MCP-HT260 (probe: HRS) available from Mitsubishi Petrochemical Co., Ltd.

Then, in this method, the suspension board with circuit 1 in a production process having the semiconductive layer 10 doped with the conductive polymer is further washed with water.

In the method for producing the suspension board with circuit 1, since the standard electrode potential of the conductive material of the conductive pattern 4 is lower than the oxidation-reduction potential of the polymeric liquid of the conductive polymer, the oxidation power of the polymeric liquid of the conductive polymer becomes lower than that of the conductive material that forms the conductive pattern 4. Therefore, when the suspension board with circuit 1 before the semiconductive layer 10 is formed is dipped in the polymeric liquid of the conductive polymer, the conductive material of the conductive pattern 4 is less likely to be dissolved in the polymeric liquid even if the conductive material in the terminal portion 7 is exposed.

Accordingly, the semiconductive layer 10 can be formed on the surface of the insulating cover layer 5 and the surface of the insulating base layer 3 while corrosion in the terminal portion 7 can be prevented.

As a result, static electricity charged on the resulting suspension board with circuit 1 can be efficiently removed while discoloration in the terminal portion 7 can be prevented.

In the method for producing the suspension board with circuit 1, in order to protect the terminal portion 7, the plating layer 8 is formed on a surface thereof. However, when the suspension board with circuit 1 is dipped in the polymeric liquid of the conductive polymer, the polymeric liquid permeates the interface between the peripheral end portion of the plating layer 8, and the insulating cover layer 5 and the insulating base layer 3, which may corrode the terminal portion 7. However, in this method, since the oxidation power of the polymerization liquid of the conductive polymer becomes lower than that of the conductive material that forms the conductive pattern 4, the conductive material in the terminal portion 7 is less likely to be dissolved in the polymeric liquid. Therefore, such corrosion is less likely to occur, whereby discoloration in the terminal portion 7 can be effectively prevented.

In this method, in the case where the conductive material of the conductive pattern 4 of the suspension board with circuit 1 before the semiconductive layer 10 is formed is copper, and the polymeric liquid of the conductive polymer contains sulfonic acid, the oxidation power of the polymeric liquid can be reliably adjusted lower than that of the conductive pattern 4. Therefore, in the terminal portion 7, dissolution of the copper in the polymeric liquid is reliably suppressed.

Accordingly, the corrosion in the terminal portion 7 can be reliably prevented. As a result, the discoloration in the terminal portion 7 can be reliably prevented.

In the method for producing the suspension board with circuit 1, in the case where the conductive polymer is polyaniline, the resulting suspension board with circuit 1 can more efficiently remove static electricity charged thereon.

In the above explanation, the wired circuit board of the present invention has been illustrated and described with the suspension board with circuit 1. However, the wired circuit board of the present invention is not limited thereto, and can be widely applied to other wired circuit boards, such as a single-sided flexible wired circuit board, a double-sided flexible wired circuit board, or a multilayered flexible wired circuit board, or further various flexible wired circuit boards having the metal supporting board 2 provided as a reinforcing layer.

### EXAMPLE

While in the following, the present invention is described in further detail with reference to Examples and Comparative Example, the present invention is not limited to any of them by no means.

(Production of Suspension Board with Circuit)

### Example 1

A metal supporting board made of a 20 μm thick stainless steel was prepared (cf. FIG. 3(a)).

Subsequently, a varnish of photosensitive polyamic acid resin was uniformly coated over an upper surface of the metal supporting board using a spin coater. The coated varnish was then heated at 90° C. for 15 minutes to form a base coating. Thereafter, the base coating was exposed to light at 700 mJ/cm² via a photomask, and then heated at 190° C. for 10 minutes. The base coating thus heated was then developed using an alkaline developer. Subsequently, the coating was cured at 385° C. under the pressure reduced to 1.33 Pa, thereby forming an insulating base layer of polyimide on the metal supporting board in the above-mentioned pattern (cf. FIG. 3 (b)). The insulating base layer thus formed had a thickness of 10 μm.

Next, a conductive pattern made of a 15 μm thick copper (standard electrode potential (25° C.): 0.337 V) was formed in the above-mentioned pattern by an additive method (cf. FIG. 3 (c)). The spacing between each of the wires was 30 μm, and each of the wires had a width of 30 μm. Each of the terminal portions had a length of 200 μm and a width of 200 μm.

Next, the varnish of the photosensitive polyamic acid resin described above was uniformly coated over the upper surface of the metal supporting board including the conductive pattern and the insulating base layer using a spin coater. The coated varnish was then heated at 90° C. for 10 minutes to form a cover coating having a thickness of 15 μm. Thereafter, the cover coating was exposed to light at 700 mJ/cm² via a photomask, and then heated at 180° C. for 10 minutes. The cover coating thus heated was then developed using an alkaline developer to pattern the cover coating. Subsequently, the cover coating was cured at 385° C. under the pressure reduced to 1.33 Pa. As a result, an insulating cover layer of polyimide was formed on the insulating base layer in the pattern that covers the wires and exposes the terminal portions (cf. FIG. 3 (d)). The insulating cover layer had a thickness of 5 μm.

Next, after a plating resist was formed on the metal supporting board, a gold plating layer was formed on the surfaces of the terminal portions by electroless gold plating, and thereafter, the plating resist was removed (cf. FIG. 4 (e)). The gold plating layer thus formed had a thickness of 2.5 μm.

Next, a semiconductive layer was formed on the surface of the insulating cover layer and the surface of the insulating base layer (cf. FIG. 4 (f)).

To form the semiconductive layer, first, about 300 g of pure water and 2.5 g of aniline were sequentially added to 3.9 g of methanesulfonic acid, and the mixture was cooled to 10° C. with being stirred to prepare a polymeric liquid of polyaniline. Then, separately, 20 g of pure water was added to 10.7 g of ammonium peroxodisulfate (ammonium persulfate: APS), and the mixture was stirred until dissolved. The dissolved mixture was cooled to 10° C. to prepare a polymerization initiator aqueous solution.

Then, the above-mentioned suspension board with circuit in a production process was dipped in the above-mentioned polymeric liquid of polyaniline, and the polymerization initiator aqueous solution was also added thereto and mixed. Thereafter, the suspension board with circuit was further kept dipped at 10° C. for 12 minutes to polymerize aniline, so that polyaniline was deposited on the surface of the insulating base layer and the surface of the insulating cover layer.

In the polymeric liquid to which the polymerization initiator was added, the concentration of aniline was 0.05 mol/L, the concentration of methanesulfonic acid was 0.08 mol/L, and the concentration of ammonium peroxodisulfate was 0.09 mol/L. The polymeric liquid had an oxidation-reduction potential (25° C.) of 0.3 V.

Then, the suspension board with circuit in a production process was withdrawn from the polymeric liquid and then washed with water. Thereafter, the suspension board with circuit in a production process was dipped in a doping agent aqueous solution containing p-phenolsulfonic acid novolac resin (PPSA) of 20% by weight concentration at 60° C. for 10 minutes to dope the semiconductive layer with polyaniline. Subsequently, the doped semiconductive layer was washed with water. The doped semiconductive layer made of polyaniline had a thickness of 0.03 μm, and also had a surface resistance value in the range of 1×10⁷ to 1×10⁸Ω/□.

### Example 2

A suspension board with circuit was obtained in the same method as in Example 1 except that 9.3 g of sodium iodate was used instead of 10.7 g of ammonium peroxodisulfate in Example 1.

In the polymeric liquid to which the polymerization initiator was added, the concentration of sodium iodate was 0.09 mol/L and the oxidation-reduction potential (25° C.) of the polymeric liquid was 0.2 V.

### Comparative Example 1

The suspension board with circuit was obtained in the same method as Example 1 except that 2.0 g of 98% concentrated sulfuric acid was used instead of 3.9 g of methanesulfonic acid in Example 1.

In the polymeric liquid to which the polymerization initiator was added, the concentration of sulfuric acid was 0.04 mol/L and the oxidation-reduction potential (25° C.) of the polymeric liquid was 1.2 V

(Evaluation)

The terminal portions in the suspension boards with circuit obtained in Examples 1 and 2 and Comparative Example 1 were visually observed.

No discoloration was observed on the terminal portions in the suspension boards with circuit of Examples 1 and 2.

However, discoloration was observed on the terminal portion in the suspension board with circuit of Comparative Example 1.

While the illustrative embodiments of the present invention are provided in the above description, such is for illustrative purpose only and it is not to be construed limitative. Modification and variation of the present invention that will be obvious to those skilled in the art is to be covered by the following claims.

What is claimed is:

1. A method for producing a wired circuit board, comprising the steps of:
preparing a wired circuit board comprising an insulating layer and a conductive pattern having a wire covered with the insulating layer and a terminal portion exposed from the insulating layer; and
forming a semiconductive layer on a surface of the insulating layer by dipping the wired circuit board in a polymeric liquid of a conductive polymer,
wherein an oxidation-reduction potential of the polymeric liquid of the conductive polymer is lower than a standard electrode potential of a conductive material forming the conductive pattern.

2. The method for producing a wired circuit board according to claim 1, wherein in the step of preparing the wired circuit board,
a plating layer is formed on a surface of the terminal portion.

3. The method for producing a wired circuit board according to claim 1,
wherein the conductive material of the conductive pattern is copper, and
the polymeric liquid contains sulfonic acid.

4. The method for producing a wired circuit board according to claim 1, wherein the conductive polymer is polyaniline.
